(19) United States
(12) Patent Application Publication
(10) Pub. No.: US 2024/0121977 A1
(43) Pub. Date: Apr. 11, 2024

(54) Tandem OLED with Intermediate Alloy Layer

(71) Applicant: eMagin Corporation, Hopewell Junction, NY (US)

(72) Inventors: Fangchao ZHAO, Hopewell Junction, NY (US); Howard LIN, Hopewell Junction, NY (US); Ilyas I. KHAYRULLIN, Hopewell Junction, NY (US); Kerry TICE, Hopewell Junction, NY (US); Timothy CONSIDINE, Hopewell Junction, NY (US); Laurie SZIKLAS, Hopewell Junction, NY (US); Amalkumar P. GHOSH, Hopewell Junction, NY (US)

(21) Appl. No.: 18/376,959

(22) Filed: Oct. 5, 2023

Related U.S. Application Data
(60) Provisional application No. 63/413,557, filed on Oct. 5, 2022.

(51) Int. Cl. H10K 50/19; H10K 50/13; H10K 71/60

(52) U.S. Cl. CPC H10K 50/19; H10K 50/131; H10K 71/60

(57) ABSTRACT

A tandem OLED device is provided, including an anode, a cathode, at least two electroluminescent units disposed between the anode and the cathode, and an alloy thin film disposed between the two electroluminescent units.

### CROSS-REFERENCE TO RELATED APPLICATION

This application claims priority to U.S. Provisional Patent Application Ser. No. 63/413,557, filed Oct. 5, 2022, entitled Tandem OLED with Intermediate Alloy Layer, pending.

### BACKGROUND OF THE INVENTION

The present invention relates to tandem OLED devices. More particularly, the present invention is directed to an OLED device with an intermediate layer.

An organic light-emitting diode device (OLED), commonly includes an anode, a cathode, and an organic electroluminescent layer sandwiched between the anode and the cathode. The organic electroluminescent layer commonly includes a hole-transporting layer, a light-emitting layer, and an electron-transporting layer. OLEDs are attractive because of their low drive voltage, high luminance, wide viewing-angle, and capability for full color displays and for other applications. Tang et al. described a multilayer OLED in their U.S. Pat. Nos. 4,769,292 and 4,885,211.

OLEDs can emit different colors, such as red, green, blue, or white, depending on the emitting property of its light emitting layer.

A tandem OLED structure (sometimes called a stacked OLED or a cascaded OLED) has been disclosed, for example, by Jones et al. in U.S. Pat. No. 6,337,492, Tanaka et al. in U.S. Pat. No. 6,107,734, Kido et al. in JP Patent Publication 2003/045676A and U.S. Published Patent Application No. 2003/0189401 A1, and Liao et al. in U.S. Pat. No. 6,717,358 and U.S. Patent Application Publication No. 2003/0170491 A1.

A tandem OLED is fabricated by stacking multiple individual OLED units vertically and driving the stack using a single power source. The advantage is that current efficiency, lifetime, or both are increased. However, problems include:
1. The tandem structure with multiple OLED units increases the driving voltage (approximately in proportion to the number of OLED units), which is not favorable for the power consumption,
2. As the voltage required increases, a larger capacitor size is required. The high voltage required for driving the OLED make it challenging to fabrication the backplane with very small pixel displays like microdisplays,

Therefore, it is essential to lower the driving voltage and improve the power efficiency of tandem OLED devices for broad applications in OLED displays.

U.S. Pat. No. 7,955,719 (Hatwar et al.) is of general background and teaches a tandem OLED device with an intermediate connector.

Notwithstanding these developments, there remains a need to improve efficiency and driving voltage of tandem OLED devices while maintaining good broadband emission.

All references cited herein are fully incorporated by reference in their entireties.

### SUMMARY OF THE INVENTION

The present invention is directed to a tandem OLED device that includes an anode, a cathode, at least two electroluminescent units disposed between the anode and the cathode, and an alloy thin film disposed between the two electroluminescent units.

The OLED units may each comprise a hole injection layer (HIL), a hole transport layer (HTL), an electron blocking layer (EBL), an emissive layer (EML), a hole blocking layer (HBL), an electron transport layer (ETL) and/or an electron injection layer (EIL). The alloy film may be disposed between a p-type film and an n-type film. The alloy film may include comprises a first metal and a second metal or a first metal, a second metal and a third metal. The alloy film may be bilayer, including a first layer including two different metals, and a second layer including a third metal. The first metal may be, for example a precious metal. The second metal may be, for example, an alkaline earth metal or a rare earth metal. The third metal may be, for example, an alkali metal halide or an organic compound including an alkali metal. Each of the first metal, the second metal and the third metal may be co-deposited by thermal evaporation to make the alloy film. The thickness of the alloy film may be, for example, from 1 nm to 8 nm.

### BRIEF DESCRIPTION OF THE DRAWINGS

FIG. 1 is a simplified isometric view of a tandem OLED architecture with an alloy film connecting the OLED units in accordance with an exemplary embodiment of the present invention. Two or more OLED units can be stacked in the tandem OLED.

FIG. 2 is a graph of current density vs. voltage (J-V) of tandem OLEDs in accordance with the present invention using three different metals as an intermediate layer.

### DETAILED DESCRIPTION

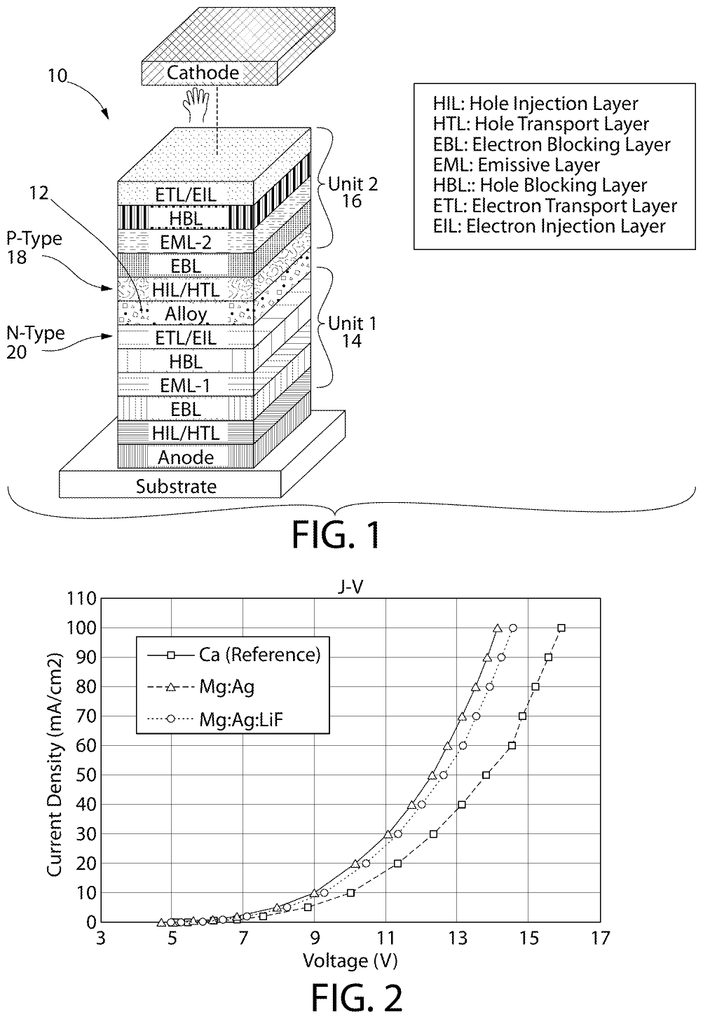

Referring now to the drawing figures wherein like reference numbers refer to like elements throughout the several views, there is shown in FIG. 1 a tandem OLED 10 with an alloy thin film 12 as an intermediate layer between OLED units 14, 16 in accordance with an exemplary embodiment of the present invention. The tandem OLED 10 includes two or more typical OLED units each including a hole injection layer (HIL), a hole transport layer (HTL), an electron blocking layer (EBL), an emissive layer (EML), a hole blocking layer (HBL), an electron transport layer (ETL) and an electron injection layer (EIL).

The alloy thin film 12 is disposed between a p-type film 18 and an n-type film 20. The alloy film 12 may be one layer and may consist of two materials (e.g., metal 1 and metal 2) or three materials (e.g., metal 1, metal 2 and material 3). The alloy film can be a bilayer including metal 1 and metal 2 as one layer, and material 3 as another layer. Metal 1 may be, for example, a precious metal (e.g., Ag, Au, Pt), with the weight ratio of 1%-99% in the alloy. Metal 2 may be, for example, an alkaline earth metal (e.g., Mg or Ca), or a rare earth metal (e.g., Yb), with the weight ratio of 1%-99% in the alloy. Material 3 may be, for example, an alkali metal halide (e.g., LiF, CsF) or an organic compound including Alkali metal (e.g., LiQ). Metal 1, metal 2 and/or material 3 may be co-deposited by thermal evaporation to make the alloy film. The thickness of the alloy film may be, for example, be from 1 nm to 8 nm.

### Example

Three green tandem (2-unit) OLED devices were fabricated using Calcium, Mg:Ag alloy and Mg:Ag:LiF alloy as an intermediate thin metal film, respectively. A current density—voltage (J-V) curve of the tandem OLED devices is shown in FIG. 2. A Tandem OLED with alloy film showed lower driving voltage than that with a Ca layer. At the same current density of 50 mA/cm², the driving voltage is 13.8 V for Ca, 12.6 V for Mg:Ag and 12.3 V for Mg:Ag:LiF, respectively.

### Examples of Benefits

Using the proposed alloy layer for tandem OLED devices. Such a device would allow the following:
(1) High efficiency;
(2) Long lifetime;
(3) Low power consumption with reduced driving voltage; and
(4) Feasible for high resolution microdisplays with less voltage requirement on the backplane.

The present invention is applicable to both white OLED with color filter as well as directly patterned OLED.

It is to be understood that the disclosure teaches just one example of the illustrative embodiment and that many variations of the invention can easily be devised by those skilled in the art after reading this disclosure and that the scope of the present invention is to be determined by the following claims.

What is claimed is:

1. A tandem OLED device comprising:
(a) an anode;
(b) a cathode;
(c) at least two electroluminescent units disposed between the anode and the cathode; and
(d) an alloy thin film disposed between the two electroluminescent units.

2. The tandem OLED device of claim 1, wherein the electroluminescent units each comprise a hole injection layer (HIL), a hole transport layer (HTL), an electron blocking layer (EBL), an emissive layer (EML), a hole blocking layer (HBL), an electron transport layer (ETL) and an electron injection layer (EIL).

3. The tandem OLED device of claim 1, wherein the alloy film is disposed between a p-type film and an n-type film.

4. The tandem OLED device of claim 1, wherein the alloy film comprises a first metal and a second metal.

5. The tandem OLED device of claim 1, wherein the alloy film comprises a first metal, a second metal and a third metal.

6. The tandem OLED device of claim 1, wherein the alloy film is bilayer, comprising a first layer including two different metals, and a second layer including a third metal.

7. The tandem OLED device of claim 4, wherein the first metal is a precious metal.

8. The tandem OLED device of claim 4, wherein the second metal is an alkaline earth metal or a rare earth metal.

9. The tandem OLED device of claim 5, wherein the third metal is an alkali metal halide or an organic compound including an alkali metal.

10. The tandem OLED device of claim 5, wherein each of the first metal, the second metal and the third metal are co-deposited by thermal evaporation to make the alloy film.

11. The tandem OLED device of claim 1, wherein a thickness of the alloy film is from 1 nm to 8 nm.
